(19) United States
(12) Patent Application Publication
(10) Pub. No.: US 2025/0258972 A1
(43) Pub. Date: Aug. 14, 2025

(54) METHOD FOR RISK ESTIMATION AND VALUE DETERMINATION OF BATTERIES

(71) Applicant: HITACHI, Ltd., Tokyo (JP)

(72) Inventors: Faraz MOGHIMI, Boston, MA (US); Arnab CHAKRABARTI, Milpitas, CA (US); Amit KUMAR, San Jose, CA (US)

(21) Appl. No.: 18/440,789

(22) Filed: Feb. 13, 2024

(51) Int. Cl. G06F 30/20

(52) U.S. Cl. CPC G06F 30/20

(57) ABSTRACT

Systems and methods described herein involve providing estimated battery behavior derived from battery degradation data associated with a battery into a simulator, the simulator configured to intake user input comprising operating environment parameters, use pattern parameters, and desired output risk information to be simulated, simulating the battery with the simulator based on the operating environment parameters and the use pattern parameters to generate a failure probability distribution for the battery, the desired output risk information, and an estimated battery valuation for the battery.

### BACKGROUND

### Field

The present disclosure is generally directed to battery systems, and more specifically, for systems and methods for risk estimation and value determination for battery and battery systems.

### Related Art

Insurance is a contract in which the customer pays a premium to an insurance provider, and in exchange the insurance provider promises to financially cover potential future losses if they occur subject to conditions described in an agreement. The insurance business model is profitable only if a business is making more in premium sales than the Expected Value (EV) of future payouts (claims paid and settlement costs). As such, the principal part of an insurance practice is to efficiently and accurately estimate the EV of future payouts for each contract and to price the premium accordingly.

In the context of battery insurance or warranty, if an insurance company provides a one-size-fits-all battery insurance (warranty) premium price, they are essentially under charging the “risky” customers and over charging the “safe” customers. Since the customers have an idea regarding how risky they are, consequently only the extra “risky” customers will buy the insurance (warranty), such as excessive battery users. On the other hand, “safe” consumers know they will not benefit from purchasing a warranty and therefore do not purchase the warranty. This means the insurer will have more battery failures and fewer customers; where the only winners are the extra “risky” users and everyone else is worse off. This phenomenon is called information asymmetry adverse selection. Adverse selection is the ultimate insurance problem to be solved and is ever present in battery insurance and risk management products. One solution to adverse selection is to dynamically and accurately estimate the future expected risk of each customer based on their unique conditions and to price the premium accordingly.

As will be described herein, the term “battery” in the present disclosure is used to mean not only a single battery, but also a system of batteries.

The lithium-ion battery market is growing quite rapidly from a technological aspect; however, there is a lack of sophisticated financial services/products offered for batteries. Consequently, society may become ever more reliant on batteries, yet there are limited protections and risk management solutions available in the marketplace.

Batteries degrade with time and usage. Typically, the battery is considered as salvage when the battery capacity reaches under a threshold such as 70% or 80%. Notably, this degradation process is neither fully random nor completely predictable. Moreover, a battery's degradation process and pace are dependent on a variety of factors. As such, the degradation relationship can be to estimate the failure risks and battery values long into the future.

### SUMMARY

Societies are becoming more and more reliant on batteries with increasing electrification. Naturally, as batteries fail with time and usage, one major challenge is to predict when and with what probabilities batteries will fail in the future, and what financial impact such failures will have. In other words, as an organization reliant on batteries, it is essential to quantitatively gauge battery failure risk, as unexpected failure could be quite costly.

One problem in the related art is that there is not always enough data to know how a battery will perform in a wide variety of conditions over a long duration. Another problem involves estimating the financial impact of failures over a long duration in this wide variety of conditions. The example implementations described herein involve systems and methods to address the above problem.

Battery failure risk in the future is dependent on a variety of factors such as battery type, usage behavior, and climate conditions. In addition, randomness also plays a role in future battery failures. Therefore, estimating battery insurance risk and the consequent insurance premium price in a dynamic fashion is a complex task. Currently, most battery insurance plans provide a uniform one size fits all premium structure. Such static valuation and underwriting can sometimes be economically unviable and can lead to market failure with adverse consequences for battery adoption. The example implementations described herein can address this problem by dynamically estimating battery failure risk and battery insurance premium on a case-by-case basis.

Further, the battery degradation process is not fully random as it is dependent on various factors. There is a need to determine how to assign a value to a used battery given such various factors. This problem becomes increasingly more important if high value batteries are involved, as slight differences in past usage or climate can project significant value deviations. Example implementations described herein provide a solution that dynamically estimates the value of used batteries.

Example implementations described herein involve an end-to-end quantitative method that can estimate how battery capacity degrades with time under a variety of conditions long into the future, accurately and dynamically estimate future risk and value of battery under different circumstances that a user cares about, and dynamically calculate the risk and underlying value of a battery as needed by the stakeholders, such as in an insurance contract or for a secondhand battery.

Aspects of the present disclosure can involve a method, which can involve providing estimated battery behavior derived from battery degradation data associated with a battery into a simulator, the simulator configured to intake user input involving operating environment parameters, use pattern parameters, and desired output risk information to be simulated, simulating the battery with the simulator based on the operating environment parameters and the use pattern parameters to generate a failure probability distribution for the battery, the desired output risk information, and an estimated battery valuation for the battery.

Aspects of the present disclosure can involve a computer program, which can involve instructions involving providing estimated battery behavior derived from battery degradation data associated with a battery into a simulator, the simulator configured to intake user input involving operating environment parameters, use pattern parameters, and desired output risk information to be simulated, simulating the battery with the simulator based on the operating environment parameters and the use pattern parameters to generate a failure probability distribution for the battery, the desired output risk information, and an estimated battery valuation for the battery. The computer program and instructions can be stored on a non-transitory computer readable medium and executed by one or more processors.

Aspects of the present disclosure can involve a system, which can involve means for providing estimated battery behavior derived from battery degradation data associated with a battery into a simulator, the simulator configured to intake user input involving operating environment parameters, use pattern parameters, and desired output risk information to be simulated, means for simulating the battery with the simulator based on the operating environment parameters and the use pattern parameters to generate a failure probability distribution for the battery, the desired output risk information, and an estimated battery valuation for the battery.

Aspects of the present disclosure can involve an apparatus, which can involve a processor configured to provide estimated battery behavior derived from battery degradation data associated with a battery into a simulator, the simulator configured to intake user input involving operating environment parameters, use pattern parameters, and desired output risk information to be simulated, simulate the battery with the simulator based on the operating environment parameters and the use pattern parameters to generate a failure probability distribution for the battery, the desired output risk information, and an estimated battery valuation for the battery.

### BRIEF DESCRIPTION OF DRAWINGS

FIG. 1 illustrates an overall structure of the example implementations described herein.

FIG. 2 illustrates an example of the overall sequence of the functionalities within the framework, in accordance with an example implementation.

FIG. 3 illustrates examples of data, in accordance with an example implementation.

FIG. 4 illustrates the overall structure of the estimator module, in accordance with an example implementation.

FIG. 5 illustrates an example of user input, in accordance with an example implementation.

FIG. 6 illustrates an example of the distribution of user input, in accordance with an example implementation.

FIG. 7 illustrates an example of the user input and the estimated model/estimated battery behavior being provided to a simulation module, in accordance with an example implementation.

FIG. 8 illustrates the risk analysis and valuation module 104, in accordance with an example implementation.

FIG. 9 illustrates an example of a valuation method such as an area under a curve, in accordance with an example implementation.

FIG. 10 illustrates an example risk and value report involving the valuation of insurance warranties, in accordance with an example implementation.

FIG. 11 illustrates an example risk and value report involving a dashboard showing minimum viable premium, in accordance with an example implementation.

FIG. 12 illustrates an example risk and value report dashboard for a used battery depending on location, in accordance with an example implementation.

FIG. 13 illustrates an example computing environment with an example computer device suitable for use in some example implementations.

### DETAILED DESCRIPTION

The following detailed description provides details of the figures and example implementations of the present application. Reference numerals and descriptions of redundant elements between figures are omitted for clarity. Terms used throughout the description are provided as examples and are not intended to be limiting. For example, the use of the term “automatic” may involve fully automatic or semi-automatic implementations involving user or administrator control over certain aspects of the implementation, depending on the desired implementation of one of ordinary skill in the art practicing implementations of the present application. Selection can be conducted by a user through a user interface or other input means or can be implemented through a desired algorithm. Example implementations as described herein can be utilized either singularly or in combination and the functionality of the example implementations can be implemented through any means according to the desired implementations.

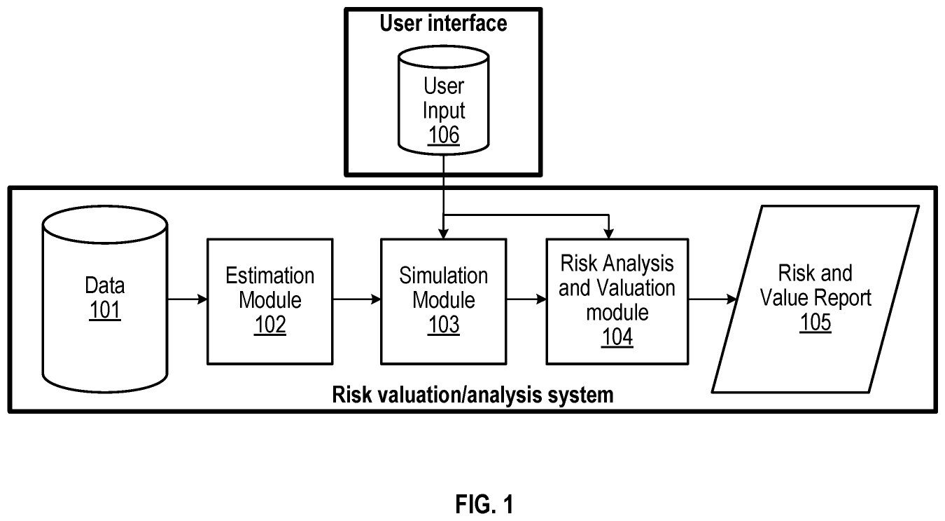

FIG. 1 illustrates an overall structure of the example implementations described herein. The method involves several modules as illustrated in FIG. 1 and summarized as follows.

In the risk valuation/analysis system as proposed herein, the following modules can be involved.

Data 101: this data can include battery degradation data, climate data, user data, other meta data, and so on. In other words, any data source that can inform how batteries work under different conditions can be included here. In addition, this data can also include other relevant meta data (such as economic data, geo spatial data, and so on) that can inform other modules.

Estimation Module 102: In this module, an estimator is constructed that predicts battery capacity and battery capacity degradation under various conditions into the future. This estimator leverages the data with a modeling framework to achieve this task. The modeling framework can take many forms such as a supervised machine learning algorithm, more generally an artificial intelligence model, a statistical model, a formulaic approach inspired by the chemistry of a particular type of battery, and so on in accordance with the desired implementation. In addition, the estimator is validated, and optimized within this module.

Simulation module 103: In this module, the framework interacts with the user and takes input about the scenarios that a user cares about (described with respect to user input 106). Next, it utilizes the estimator from estimation module 102 to generate many simulations with stochasticity and randomness in scenarios that the user wants. These simulations represent a stochastic representation of how battery capacity and battery life will turn out under the desired constraints and scenarios. Finally, the simulation results, statistics, and meta data are aggregated and passed to the next module as a simulation report.

Risk Analysis and Valuation Module 104: Risk analysis quantifies the frequency and severity of outcomes produced by the simulation module over time. For example, it may calculate the chance of battery failure in a specified user scenario. Common risk metrics include measures of outcome variance and tail risk. Valuation uses the simulation report data, risk metrics, and user input preferences and outputs the one or more measures of value. In terms of methodology, this module uses statistics and asset pricing. Depending on the desired implementation, it may use a discounting mechanism. Depending on the desired implementation, it may also consider the utility function of the user to arrive at value or price from the user's perspective. The combination of risk analysis and valuation can result in many metrics of economic interest such as: battery warranty/insurance premium, future battery risk, inherent battery value, battery insurance contract details, and so on.

Risk and Value Report 105: This module is the output of the framework in the form of numbers, data, tables, text, dashboards, user interface, and so on in accordance with the desired implementation. The format of the output is dependent on the user input 106.

User Input 106: This is the module where a user can interact with the framework and specify the problem and scenarios that they are interested in through a user interface. For example, an insurance provider in the United States might be interested in getting premium estimation across 100 locations, with 50 types of usage behavior. Another user might be interested in identifying the optimum years of warranty to be sold under certain conditions. Alternatively, a user might seek to determine the underlying value of a specific type of battery that has been used in a certain condition. This input data can include but is not limited to functionalities needed from the framework, scenario design choices, required output types, and scenario data points.

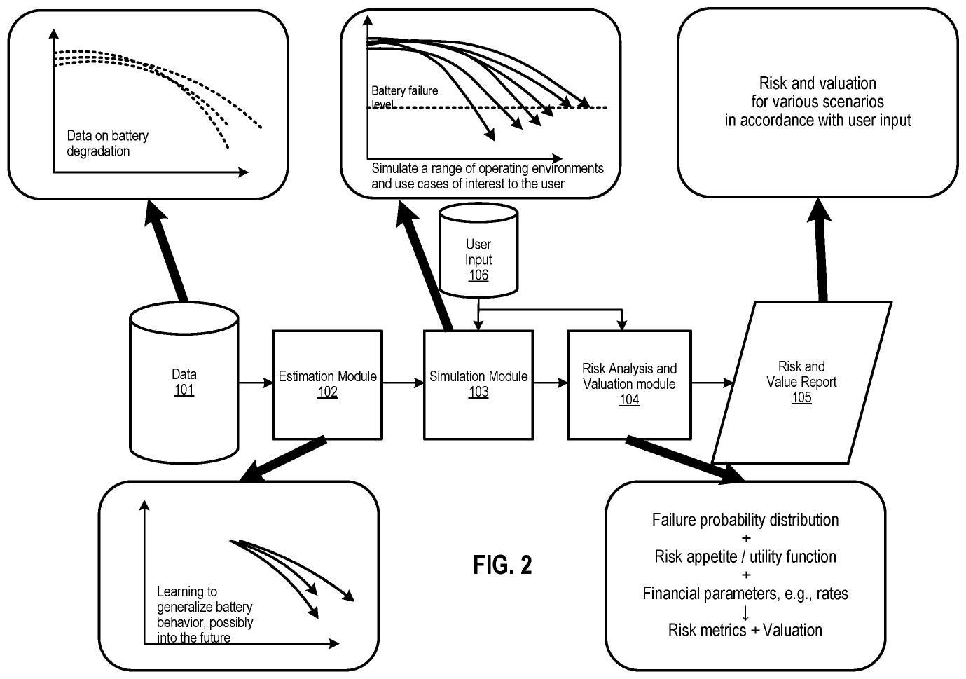

FIG. 2 illustrates an example of the overall sequence of the functionalities within the framework, in accordance with an example implementation. As illustrated in FIG. 2, data 101 can involve battery degradation in the form of time series data, which can be derived from the data regarding the battery capacity, the environment data, and so on.

Output of the estimation module 102 is an estimator that generalizes the pattern of decline of battery capacity. The block may be implemented using machine learning (ML), more generally artificial intelligence (AI), through statistical modeling, using a formulaic approach that captures the battery's chemistry and response to physical environment, and so on in accordance with the desired implementation. In theory, this module finds a function that can map the following, although the form of this function is not always explicitly known in some implementations:

Battery capacity estimator equation:

capacity(t)=F(ambient temperature,cycle,capacity(t−1),other factors)

As illustrated in FIG. 2, the simulation module 103 can involve generating random simulation scenarios from the use pattern parameters and the operating environment parameters within a range of conditions from the estimated battery behavior; and using a plurality of predicted battery capacities over time from the estimated battery behavior to generate the desired output risk information to be simulated over the random simulation scenarios (e.g., battery failure level over time).

The risk analysis and valuation module 104 can be configured to determine the failure probability distribution of the battery, the risk appetite, the financial parameters, and risk metrics in accordance with the desired implementation.

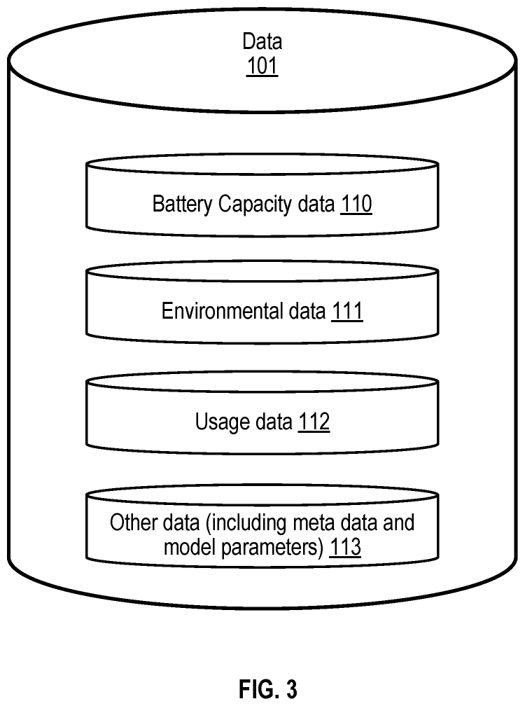

FIG. 3 illustrates examples of data 101, in accordance with an example implementation. Examples of data can include, but are not limited to, battery capacity data 110, environmental data 111, usage data 112, or other data 113 in accordance with the desired implementation. Other data can include, but is not limited to, metadata, model parameters, and so on.

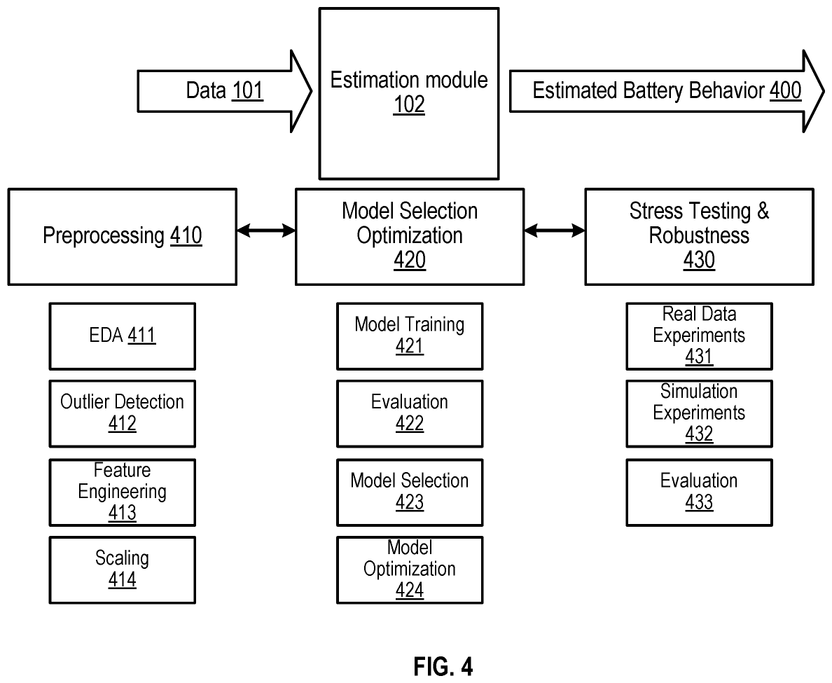

FIG. 4 illustrates the overall structure of the estimator module 102, in accordance with an example implementation. The number of independent variables used in the battery capacity estimator equation can be expanded to expand the capabilities of the model. In an example ML-based implementation of this module 102, preprocessing 410, model selection optimization 420, and stress testing 430 sub modules exist to ensure that a robust and accurate estimator is used. The goal of stress testing is to ensure that the estimator's output (e.g., estimated battery behavior 400) will produce reasonable outcomes in a wide range of scenarios, including those not captured by the estimator's training data.

In example implementations as described herein, the estimated battery behavior 400 is derived from data 101, which can involve battery degradation data as derived from battery capacity data 110 through use of the battery capacity estimator equation as described herein. Such estimated battery behavior 400 is provided to a simulator 103.

In preprocessing 410 in FIG. 4, EDA 411 stands for Exploratory Data Analysis. Battery data is often corrupted by noise and outliers. In an example implementation, an outlier detection 412 process such as the Isolation Forest method can be utilized to detect and remove outliers. The core features in the machine learning formulation of this problem include temperature and cycle index. To permit the modeling of non-linearity, polynomials of order up to three are permitted to generate potential features for the feature engineering 413, which can then undergo scaling 414 to standardize data points in accordance with the desired implementation.

For the model selection optimization 420, the model training 421 can involve techniques such as ridge regression, which is a method chosen to mitigate multi-collinearity by automatically incorporating regularization. During the evaluation 422 and optimization 424, hyperparameters are selected to achieve the desired tradeoff between bias and variance until a desired model is selected at model selection 423.

The estimation module 102 generally needs to be re-trained for each type of battery, and possibly for different batches or variants of the same battery unless they are substantially identical. During the stress testing and robustness 430, real data experiments 431, and simulation experiments 432 are applied to the selected model to evaluate the model at evaluation 433. Sometimes additional data may become available later, which may call for re-training to improve estimation.

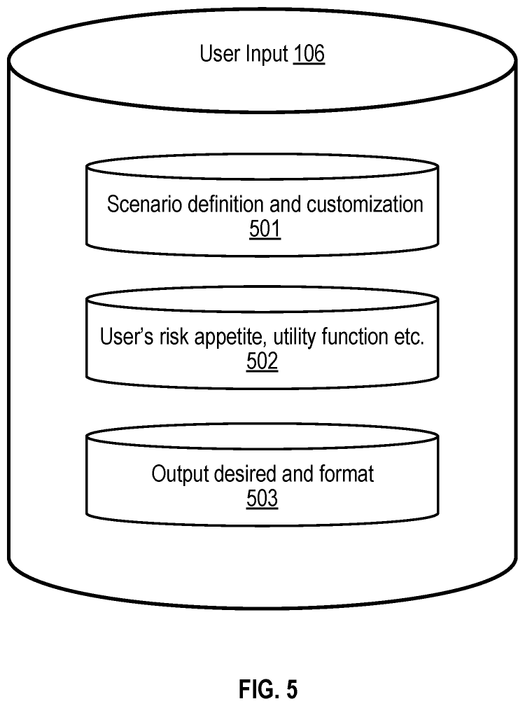

FIG. 5 illustrates an example of user input 106, in accordance with an example implementation. In this module the user can interact with the framework and define factors such as the needed system functionality, scenario definitions 501 such as number of scenarios operating environments (e.g., locations) or use patterns (e.g., degree of randomness, battery types, user types, etc.), measures of risk appetite or economic utility 502, and specifics about the desired output 503 (e.g., risk metrics, warranty premium, etc.).

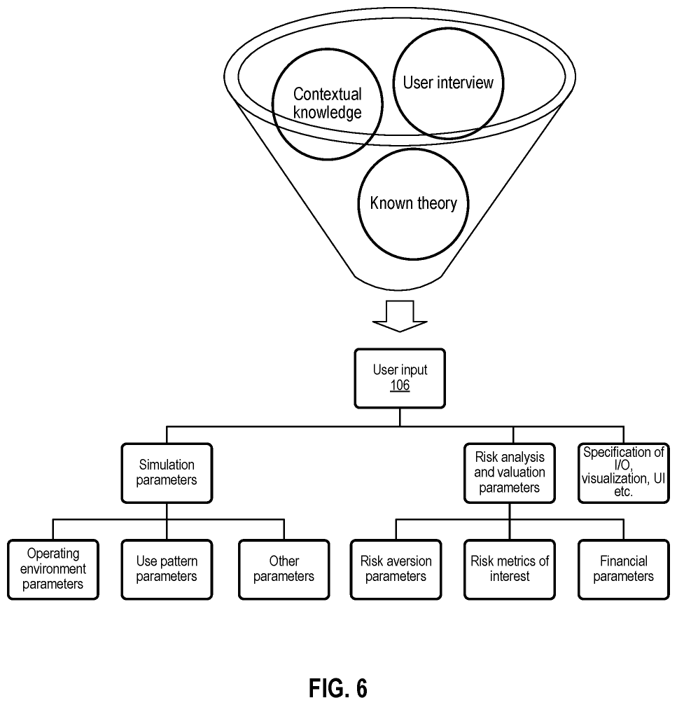

FIG. 6 illustrates an example of the distribution of user input, in accordance with an example implementation. As illustrated in FIG. 6, the user input can include contextual knowledge, domain knowledge or known theory, as well as data from interviewing the user. Such user input 106 is utilized to determine simulation parameters, such as operating environment parameters, use pattern parameters, and other parameters in accordance with the desired implementation. User input can also be utilized to determine risk analysis and valuation parameters, such as risk aversion parameters, risk metrics of interest, and financial parameters in accordance with the desired implementation. In addition, user input 106 can be utilized to specify the I/O (Input/Output), visualization of results, user interface, and so on.

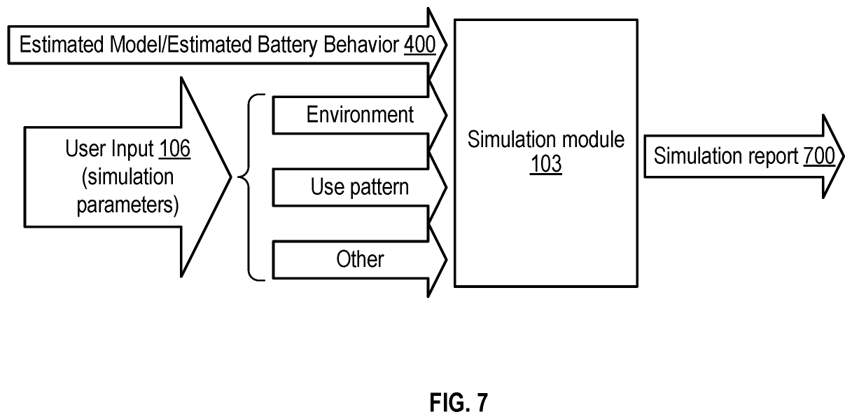

FIG. 7 illustrates an example of the user input 106 and the estimated model/estimated battery behavior 400 being provided to a simulation module 103, in accordance with an example implementation. As shown in FIG. 7, the simulator 103 is configured to intake user input 106 which can involve operating environment parameters, use pattern parameters, and other information such as the desired output risk information. The simulator 103 can simulate the battery based on the operating environment parameters and the use pattern parameters to generate a failure probability distribution for the battery, the desired output risk information, and an estimated battery valuation for the battery in a simulation report 700.

Specification of the user input is a key ingredient of the present disclosure. The example implementations described herein addresses the fundamental pain point that battery performance data is seldom available for scenarios that the user cares about. Post-estimation, the user input informs the simulation module 103 to simulate how the batteries would perform in situations that the user actually cares about. The outcomes of these simulations in turn drive risk analysis 104.

In an example implementation, input 106 can include User characteristic/environment (e.g. shared ride driver, taxi driver, remote worker, etc.) Usage pattern (e.g. driving season, frequency etc.), and other parameters such as location of usage (e.g. home address of users), which is input by the user via the user interface communicated to the risk valuation/analysis system. These inputs are used to carry out simulation. User input can sometimes be in a form that is not directly usable in simulation, risk analysis and valuation. Subjective user input can be translated into parameters that impact the subsequent modules. This translation can be through a combination of user interview, contextual knowledge and known theoretical constructs.

For example, suppose that a simple simulation requires knowledge of the battery's surrounding temperature and user cycle alone. If the battery is a car battery that is exposed to the environment, then weather data at the battery's location can be used to supply temperature. Similarly, if the user is described as a full-time shared ride driver, then driving statistics of shared ride drivers (e.g. mean of 30,000 miles/year) can be combined with miles-per-charge to inform cycling. These are examples of contextual knowledge.

The user's risk appetite or economic utility function can be estimated with a combination of user interview and known theory. One example is the use of a questionnaire to map a user's behavior in reference to a model. For a discounted cash flow analysis to calculate net present value, the user's cost of borrowing can be found by asking the user.

Simulation module 103 uses the estimated battery behavior 400 and other output from the estimator model, as well as the scenarios defined by or of interest to the user to generate a range of simulated battery outcomes in a simulation report 700. More specifically, this module receives the environmental data, the estimator model, and user specification input and conducts the following:
Step 1: Generate many random simulation scenarios within the range of interest defined by the user.
Step 2: After the scenarios are set, using the estimator model, the simulation framework generates the sequential states, capacities, and other parameters of the battery in each scenario.
Step 3: A report is created recording the sequential states, capacities, relevant meta data and statistics.

Ultimately, this module simulates what could happen in the real world in varying circumstances. This output data is then used in the risk analysis and valuation module 104.

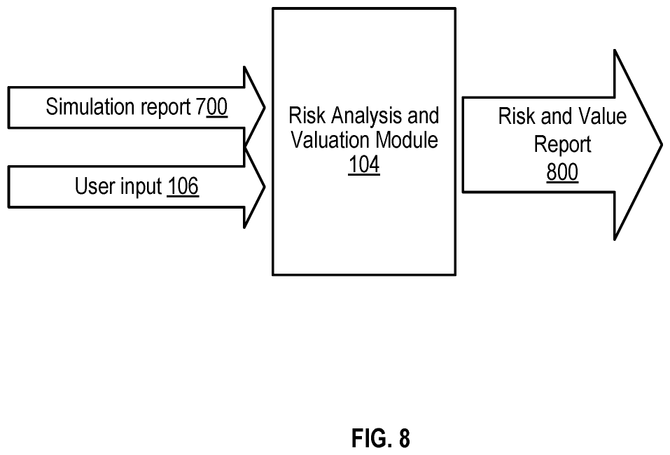

FIG. 8 illustrates the risk analysis and valuation module 104, in accordance with an example implementation. This module uses the simulation report data and user input preferences and outputs the final risk analysis and valuation report or user interface (UI). In terms of methodology, this module mainly uses statistics and methods in valuation or asset pricing.

With respect to risk analysis, the simulation step provides a distribution of how many days it would take for a battery to fail (under 70% capacity, for example) under many scenarios, and randomness (stochasticity). This in turn allows the example implementations to calculate the probability of a battery failing within a time frame (e.g., within the next ten years). In other words, the proposed framework can estimate the probability of battery failing over a stated time horizon when operated in user-specified conditions. Consequently, the framework can now calculate risk metrics based on the users' risk tolerance (which is a component of user input) and the price of replacement.

With respect to battery and warranty valuation, the valuation may be based on a range of methods, such as net present value of warranty payouts, an economic utility function applied to future outcomes such as payouts at specific times, simpler functions based on statistics of payouts or losses such as expected loss plus a profit margin, or other methods as described herein.

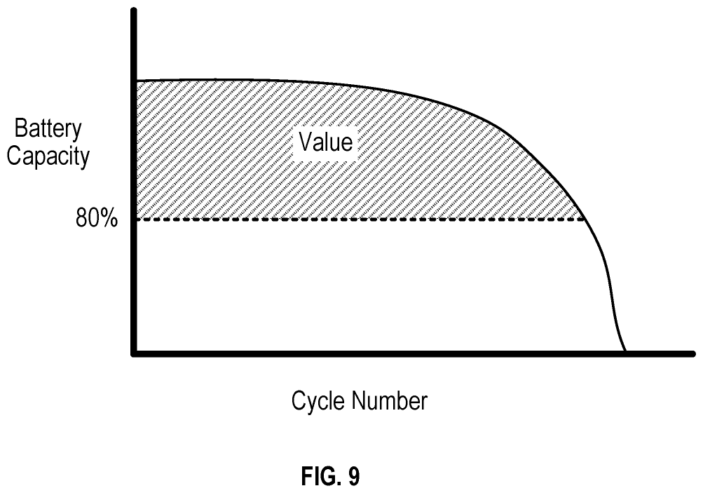

FIG. 9 illustrates an example of a valuation method such as an area under a curve, in accordance with an example implementation. In this example implementation, there is one specific method in which the value of a battery is the area under the curve of the battery capacity until it reaches failure capacity such as 80%. With that context, now using the same simulation report and the estimator model, users can project future capacities, and price the battery accordingly.

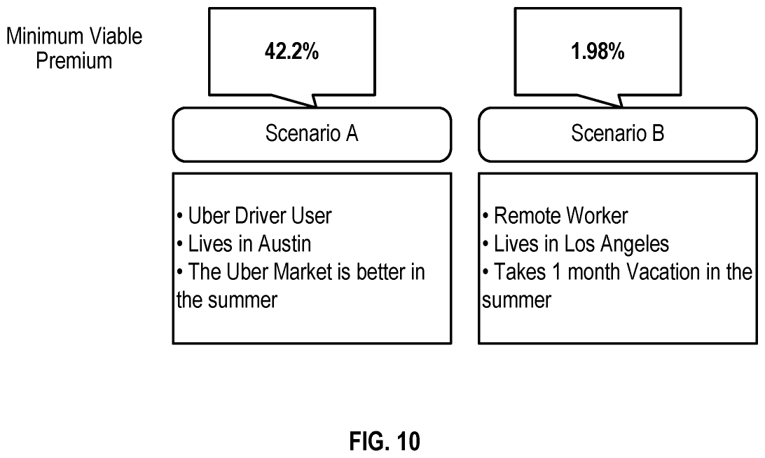

The Risk and Value Report 800 is the output of the framework. It can take many forms such as tables, data, dashboard, web/app user Interface, dictionary, and so on, in accordance with the desired implementation. The output format may depend on the user's preferences as defined in the user input 106. Some examples of such reports are illustrated in FIGS. 10-12.

FIG. 10 illustrates an example risk and value report involving the valuation of insurance warranties, in accordance with an example implementation. As described herein, battery capacity degrades with time and usage. This degradation process is neither uniform nor fully random. As such, the degradation process is dependent on a variety of factors such as usage climate, battery type, usage pattern, and so on. Moreover, described herein, the premium of insurance and warranty products should be calculated on a case-by-case basis to avoid adverse selection and its consequences.

Example implementations described herein can be used to calculate the premium of insurance and warranty products offered for batteries. In addition, the example implementations can be used to estimate the optimal contract details from the insurance or manufacturer point of view. For instance, imagine two EV drivers with the following simple circumstances seeking to purchase battery warranty for their vehicle. The example implementations can estimate the minimum viable premium as illustrated in FIG. 10.

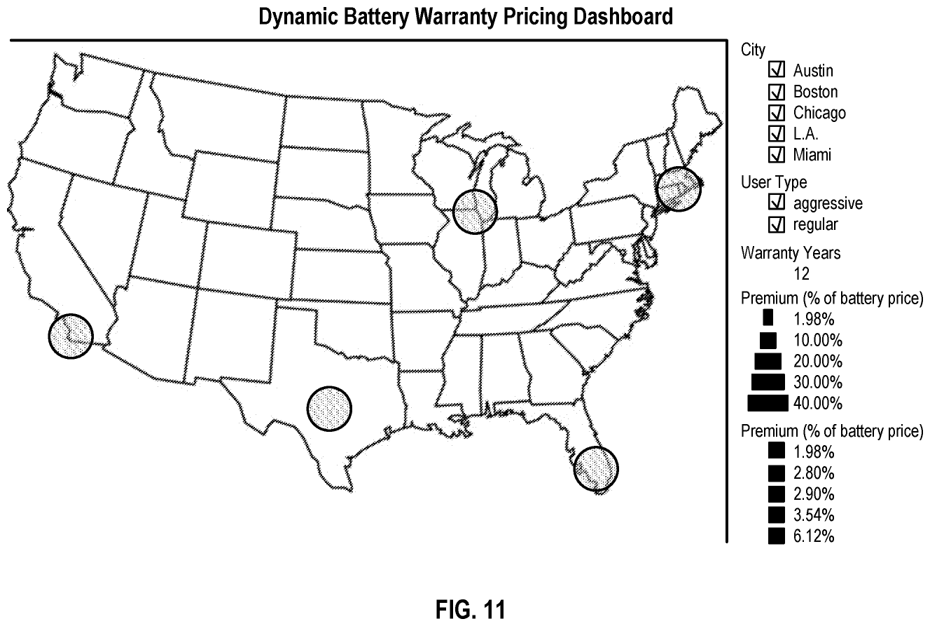

FIG. 11 illustrates an example risk and value report involving a dashboard showing minimum viable premium, in accordance with an example implementation. The example implementations can also be utilized to generate more complicated risk and value reports in accordance with the desired implementation. As illustrated in FIG. 11, a dashboard can also be generated to provide the estimation of minimum viable premium as the percentage of a battery's value for an EV battery under various conditions in different locations.

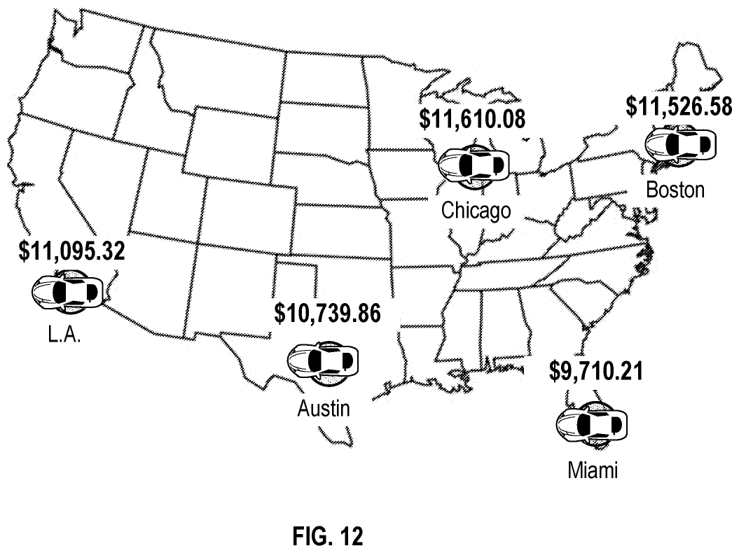

FIG. 12 illustrates an example risk and value report dashboard for a used battery depending on location, in accordance with an example implementation. The global secondary battery market is projected to reach hundreds of billions of dollars. Thus, there is a need to determine the underlying value of battery in a given market. In addition to the pure secondary battery market, there are markets where battery values are a significant portion of the value another product such as a used EV. The example implementations described herein can efficiently, dynamically estimate the underlying (inherent) value or remaining value of battery in the secondary market. This can be used by various dealers, customers, and other stakeholders in this industry.

For instance, imagine that an EV with 80,000 mileage is being sold in the secondary EV market. The value of the battery in the car may vary depending on if the market is in Boston as opposed to Miami. The intuition here is, all else being equal, climate condition variations alone cause the remaining battery value to be different in the two locations. For context, the report in FIG. 12 demonstrates the price of the used battery had it been used in five different locations.

Various businesses and operations are becoming more and more reliant on batteries. For instance, most sustainable forms of energy such as solar and wind are relying on batteries to accommodate generation volatilities. The example implementations can dynamically value battery insurance and warranty as it can estimate the probability of battery failure at different times under various conditions. Similarly, if a stakeholder such as a solar farm is interested in managing its battery risk, i.e., knowing the likelihood of batteries failing in the future, they can directly utilize this concept for such task.

Another example of this is perhaps from a planning perspective. For example, suppose a business is trying to determine the next wind farm or solar farm location. If the operation requires a significant number of batteries, identifying the optimal battery climate conditions for the site would become economically important. The introduction of new battery technologies with limited history and consequently limited field use data requires a solution that can generalize limited data to end use cases. The example implementations described herein can facilitate such a solution.

In contrast to the related art, the example implementations described herein involve a wholistic and end-to-end framework. There are no end-to-end solutions in the related art with the comprehensive range of functionalities as described herein.

Further, the related art lacks a solution that utilizes technical innovation and financial solution together for the evaluation of batteries and for facilitating battery risk management.

Depending on the desired implementation, frameworks and input data can be customized based on domain knowledge expertise or business specific information to facilitate unique needs.

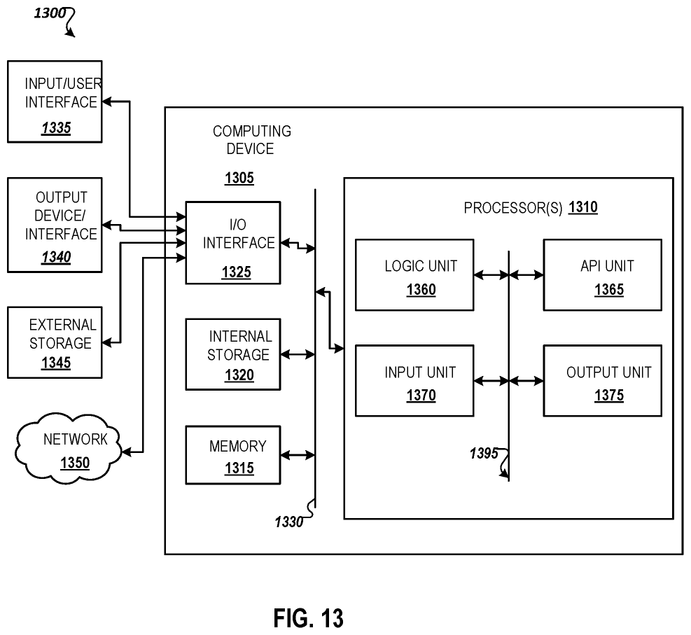

FIG. 13 illustrates an example computing environment with an example computer device suitable for use in some example implementations. Computer device 1305 in computing environment 1300 can include one or more processing units, cores, or processors 1310, memory 1315 (e.g., RAM, ROM, and/or the like), internal storage 1320 (e.g., magnetic, optical, solid-state storage, and/or organic), and/or IO interface 1325, any of which can be coupled on a communication mechanism or bus 1330 for communicating information or embedded in the computer device 1305. IO interface 1325 is also configured to receive images from cameras or provide images to projectors or displays, depending on the desired implementation.

Computer device 1305 can be communicatively coupled to input/user interface 1335 and output device/interface 1340. Either one or both of the input/user interface 1335 and output device/interface 1340 can be a wired or wireless interface and can be detachable. Input/user interface 1335 may include any device, component, sensor, or interface, physical or virtual, that can be used to provide input (e.g., buttons, touch-screen interface, keyboard, a pointing/cursor control, microphone, camera, braille, motion sensor, accelerometer, optical reader, and/or the like). Output device/interface 1340 may include a display, television, monitor, printer, speaker, braille, or the like. In some example implementations, input/user interface 1335 and output device/interface 1340 can be embedded with or physically coupled to the computer device 1305. In other example implementations, other computer devices may function as or provide the functions of input/user interface 1335 and output device/interface 1340 for a computer device 1305.

Examples of computer device 1305 may include, but are not limited to, highly mobile devices (e.g., smartphones, devices in vehicles and other machines, devices carried by humans and animals, and the like), mobile devices (e.g., tablets, notebooks, laptops, personal computers, portable televisions, radios, and the like), and devices not designed for mobility (e.g., desktop computers, other computers, information kiosks, televisions with one or more processors embedded therein and/or coupled thereto, radios, and the like).

Computer device 1305 can be communicatively coupled (e.g., via IO interface 1325) to external storage 1345 and network 1350 for communicating with any number of networked components, devices, and systems, including one or more computer devices of the same or different configuration. Computer device 1305 or any connected computer device can be functioning as, providing services of, or referred to as a server, client, thin server, general machine, special-purpose machine, or another label.

IO interface 1325 can include but is not limited to, wired and/or wireless interfaces using any communication or IO protocols or standards (e.g., Ethernet, 802.11x, Universal System Bus, WiMAX, modem, a cellular network protocol, and the like) for communicating information to and/or from at least all the connected components, devices, and network in computing environment 1300. Network 1350 can be any network or combination of networks (e.g., the Internet, local area network, wide area network, a telephonic network, a cellular network, satellite network, and the like).

Computer device 1305 can use and/or communicate using computer-usable or computer readable media, including transitory media and non-transitory media. Transitory media include transmission media (e.g., metal cables, fiber optics), signals, carrier waves, and the like. Non-transitory media include magnetic media (e.g., disks and tapes), optical media (e.g., CD ROM, digital video disks, Blu-ray disks), solid-state media (e.g., RAM, ROM, flash memory, solid-state storage), and other non-volatile storage or memory.

Computer device 1305 can be used to implement techniques, methods, applications, processes, or computer-executable instructions in some example computing environments. Computer-executable instructions can be retrieved from transitory media and stored on and retrieved from non-transitory media. The executable instructions can originate from one or more of any programming, scripting, and machine languages (e.g., C, C++, C#, Java, Visual Basic, Python, Perl, JavaScript, and others).

Processor(s) 1310 can execute under any operating system (OS) (not shown), in a native or virtual environment. One or more applications can be deployed that include logic unit 1360, application programming interface (API) unit 1365, input unit 1370, output unit 1375, and inter-unit communication mechanism 1395 for the different units to communicate with each other, with the OS, and with other applications (not shown). The described units and elements can be varied in design, function, configuration, or implementation and are not limited to the descriptions provided. Processor(s) 1310 can be in the form of hardware processors such as central processing units (CPUs) or in a combination of hardware and software units.

In some example implementations, when information or an execution instruction is received by API unit 1365, it may be communicated to one or more other units (e.g., logic unit 1360, input unit 1370, output unit 1375). In some instances, logic unit 1360 may be configured to control the information flow among the units and direct the services provided by API unit 1365, the input unit 1370, the output unit 1375, in some example implementations described above. For example, the flow of one or more processes or implementations may be controlled by logic unit 1360 alone or in conjunction with API unit 1365. The input unit 1370 may be configured to obtain input for the calculations described in the example implementations, and the output unit 1375 may be configured to provide an output based on the calculations described in example implementations.

Processor(s) 1310 can be configured to execute a method or computer instructions which can involve providing estimated battery behavior 400 derived from battery degradation data 101 associated with a battery into a simulator 103, the simulator configured to intake user input 106 comprising operating environment parameters, use pattern parameters, and desired output risk information to be simulated as illustrated in FIGS. 1 to 7, and simulating the battery with the simulator 103 based on the operating environment parameters and the use pattern parameters to generate a failure probability distribution for the battery, the desired output risk information, and an estimated battery valuation for the battery (e.g., simulation report 700). Through such an example implementation, even if the underlying battery is a new battery technologies with limited history and consequently limited field use data, the simulator can generalize limited data to end use cases.

Processor(s) 1310 can be configured to execute the method or instructions as described above, and further involve generating the estimated battery behavior from the battery degradation data associated with a battery from an estimation model (e.g., estimation module 102 as illustrated in FIG. 4) configured to intake the battery degradation data and output a plurality of predicted battery capacities over time and a range of conditions as the estimated battery behavior 400 as illustrated in FIG. 2 and FIG. 4.

Processor(s) 1310 can be configured to execute the method or instructions as described above, wherein the estimation model is a machine learning model selected from a plurality of machine learning models trained against historical data of a type of battery corresponding to the battery as illustrated at 420 to 424 of FIG. 4.

Processor(s) 1310 can be configured to execute the method or instructions as described above, wherein the desired output risk information can involve insurance risk premium as illustrated in FIGS. 10 and 11.

Processor(s) 1310 can be configured to execute the method or instructions as described above, wherein the use pattern parameters comprise driving frequency and seasonality of driving characteristics for the battery being an electric vehicle battery as described with respect to FIG. 8.

Processor(s) 1310 can be configured to execute the method or instructions as described above, wherein the operating environment parameters comprise location of the battery and weather associated with the location as described with respect to FIG. 7.

Processor(s) 1310 can be configured to execute the method or instructions as described above, wherein the simulating the battery with the simulator can involve generating random simulation scenarios from the use pattern parameters and the operating environment parameters within a range of conditions from the estimated battery behavior; and using a plurality of predicted battery capacities over time from the estimated battery behavior to generate the desired output risk information to be simulated over the random simulation scenarios as described with respect to FIG. 2 and FIG. 7.

Processor(s) 1310 can be configured to execute a method or instructions as described above, wherein the user input can include tampering information for a type of the battery, and wherein simulating the battery comprises simulating tampering from the tampering information as described above with respect to FIG. 7.

Some portions of the detailed description are presented in terms of algorithms and symbolic representations of operations within a computer. These algorithmic descriptions and symbolic representations are the means used by those skilled in the data processing arts to convey the essence of their innovations to others skilled in the art. An algorithm is a series of defined steps leading to a desired end state or result. In example implementations, the steps carried out require physical manipulations of tangible quantities for achieving a tangible result.

Unless specifically stated otherwise, as apparent from the discussion, it is appreciated that throughout the description, discussions utilizing terms such as “processing,” “computing,” “calculating,” “determining,” “displaying,” or the like, can include the actions and processes of a computer system or other information processing device that manipulates and transforms data represented as physical (electronic) quantities within the computer system's registers and memories into other data similarly represented as physical quantities within the computer system's memories or registers or other information storage, transmission or display devices.

Example implementations may also relate to an apparatus for performing the operations herein. This apparatus may be specially constructed for the required purposes, or it may include one or more general-purpose computers selectively activated or reconfigured by one or more computer programs. Such computer programs may be stored in a computer readable medium, such as a computer-readable storage medium or a computer-readable signal medium. A computer-readable storage medium may involve tangible mediums such as, but not limited to optical disks, magnetic disks, read-only memories, random access memories, solid state devices and drives, or any other types of tangible or non-transitory media suitable for storing electronic information. A computer readable signal medium may include mediums such as carrier waves. The algorithms and displays presented herein are not inherently related to any particular computer or other apparatus. Computer programs can involve pure software implementations that involve instructions that perform the operations of the desired implementation.

Various general-purpose systems may be used with programs and modules in accordance with the examples herein, or it may prove convenient to construct a more specialized apparatus to perform desired method steps. In addition, the example implementations are not described with reference to any particular programming language. It will be appreciated that a variety of programming languages may be used to implement the techniques of the example implementations as described herein. The instructions of the programming language(s) may be executed by one or more processing devices, e.g., central processing units (CPUs), processors, or controllers.

As is known in the art, the operations described above can be performed by hardware, software, or some combination of software and hardware. Various aspects of the example implementations may be implemented using circuits and logic devices (hardware), while other aspects may be implemented using instructions stored on a machine-readable medium (software), which if executed by a processor, would cause the processor to perform a method to carry out implementations of the present application. Further, some example implementations of the present application may be performed solely in hardware, whereas other example implementations may be performed solely in software. Moreover, the various functions described can be performed in a single unit or can be spread across a number of components in any number of ways. When performed by software, the methods may be executed by a processor, such as a general-purpose computer, based on instructions stored on a computer-readable medium. If desired, the instructions can be stored on the medium in a compressed and/or encrypted format.

Moreover, other implementations of the present application will be apparent to those skilled in the art from consideration of the specification and practice of the techniques of the present application. Various aspects and/or components of the described example implementations may be used singly or in any combination. It is intended that the specification and example implementations be considered as examples only, with the true scope and spirit of the present application being indicated by the following claims.

What is claimed is:

1. A method, comprising:
providing estimated battery behavior derived from battery degradation data associated with a battery into a simulator, the simulator configured to intake user input comprising operating environment parameters, use pattern parameters, and desired output risk information to be simulated; and
simulating the battery with the simulator based on the operating environment parameters and the use pattern parameters to generate a failure probability distribution for the battery, the desired output risk information, and an estimated battery valuation for the battery.

2. The method of claim 1, further comprising generating the estimated battery behavior from the battery degradation data associated with a battery from an estimation model configured to intake the battery degradation data and output a plurality of predicted battery capacities over time and a range of conditions as the estimated battery behavior.

3. The method of claim 2, wherein the estimation model is a machine learning model selected from a plurality of machine learning models trained against historical data of a type of battery corresponding to the battery.

4. The method of claim 1, wherein the desired output risk information comprises insurance risk premium.

5. The method of claim 1, wherein the use pattern parameters comprise driving frequency and seasonality of driving characteristics for the battery being an electric vehicle battery.

6. The method of claim 1, wherein the operating environment parameters comprise location of the battery and weather associated with the location.

7. The method of claim 1, wherein the simulating the battery with the simulator comprises generating random simulation scenarios from the use pattern parameters and the operating environment parameters within a range of conditions from the estimated battery behavior; and
using a plurality of predicted battery capacities over time from the estimated battery behavior to generate the desired output risk information to be simulated over the random simulation scenarios.

8. The method of claim 1, wherein the user input comprises tampering information for a type of the battery, and wherein simulating the battery comprises simulating tampering from the tampering information.

9. A non-transitory computer readable medium, storing instructions for executing a process comprising:
providing estimated battery behavior derived from battery degradation data associated with a battery into a simulator, the simulator configured to intake user input comprising operating environment parameters, use pattern parameters, and desired output risk information to be simulated; and
simulating the battery with the simulator based on the operating environment parameters and the use pattern parameters to generate a failure probability distribution for the battery, the desired output risk information, and an estimated battery valuation for the battery.

10. The non-transitory computer readable medium of claim 9, the instructions further comprising generating the estimated battery behavior from the battery degradation data associated with a battery from an estimation model configured to intake the battery degradation data and output a plurality of predicted battery capacities over time and a range of conditions as the estimated battery behavior.

11. The non-transitory computer readable medium of claim 10, wherein the estimation model is a machine learning model selected from a plurality of machine learning models trained against historical data of a type of battery corresponding to the battery.

12. The non-transitory computer readable medium of claim 9, wherein the desired output risk information comprises insurance risk premium.

13. The non-transitory computer readable medium of claim 9, wherein the use pattern parameters comprise driving frequency and seasonality of driving characteristics for the battery being an electric vehicle battery.

14. The non-transitory computer readable medium of claim 9, wherein the operating environment parameters comprise location of the battery and weather associated with the location.

15. The non-transitory computer readable medium of claim 9, wherein the simulating the battery with the simulator comprises generating random simulation scenarios from the use pattern parameters and the operating environment parameters within a range of conditions from the estimated battery behavior; and
using a plurality of predicted battery capacities over time from the estimated battery behavior to generate the desired output risk information to be simulated over the random simulation scenarios.

16. The non-transitory computer readable medium of claim 9, wherein the user input comprises tampering information for a type of the battery, and wherein simulating the battery comprises simulating tampering from the tampering information.

17. An apparatus, comprising:
a processor, configured to:
provide estimated battery behavior derived from battery degradation data associated with a battery into a simulator, the simulator configured to intake user input comprising operating environment parameters, use pattern parameters, and desired output risk information to be simulated; and
simulate the battery with the simulator based on the operating environment parameters and the use pattern parameters to generate a failure probability distribution for the battery, the desired output risk information, and an estimated battery valuation for the battery.
